(19) United States
(12) Patent Application Publication
(10) Pub. No.: US 2026/0052623 A1
(43) Pub. Date: Feb. 19, 2026

(54) WIRELESS MICROPROCESSOR MODULE

(71) Applicant: BANFi Semiconductor Co., Ltd, Taipei City (TW)

(72) Inventor: Yu Chang YANG, St. Petersburg, FL (US)

(73) Assignee: BANFi Semiconductor Co., Ltd., Taipei City (TW)

(21) Appl. No.: 19/297,136

(22) Filed: Aug. 12, 2025

(30) Foreign Application Priority Data
Aug. 13, 2024 (TW) 113208705

(51) Int. Cl. H05K 1/02

(52) U.S. Cl. CPC H05K 1/0243; H05K 2201/10098

(57) ABSTRACT

A wireless microprocessor module includes a carrier board, having an upper surface and a lower surface; a wireless microprocessor circuit structure, provided on the upper surface of the carrier board; at least one antenna pin, provided on the lower surface of the carrier board and electrically connected to the wireless microprocessor circuit structure; and an antenna connection buckle, provided on the upper surface of the carrier board and electrically connected to the wireless microprocessor circuit structure and the at least one antenna pin. In this way, the antenna connection buckle is built in the wireless microprocessor module through the antenna pin, and an antenna device may be directly connected thereto. In addition, the wireless microprocessor core of the wireless microprocessor circuit structure may enhance the emitted signals through a front-end chip of the wireless microprocessor circuit structure to avoid serious interference from noises.

### CROSS-REFERENCE TO RELATED APPLICATION

This application claims the priority of Taiwanese patent application No. 113208705, filed on Aug. 13, 2024, which is incorporated herewith by reference.

### BACKGROUND OF THE INVENTION

### 1. Field of the Invention

The present invention relates to the technical field of wireless microprocessors, in particular to a wireless microprocessor module with an antenna connection buckle.

### 2. The Prior Arts

In current processor modules that use wireless transmission, the overall circuit structure is relatively large, and an adapter must be used to connect to an antenna and then to an external connector, such as a small RF connector (i.PEX). Moreover, in some cases, RF signals are routed through an RF PAD before reaching the external connector or antenna, but this often results in signal loss and impedance mismatches. Additionally, the signal strength during use is relatively weak, thereby causing the signal transmission to be often affected by noise interference.

### SUMMARY OF THE INVENTION

A primary objective of the present invention is to provide a wireless microprocessor module with an antenna connection buckle built through an antenna pin, which may be directly connected with an antenna device; furthermore, a wireless microprocessor core of the wireless microprocessor module may enhance the transmitted signal through a front-end chip to avoid serious interference from noises.

In order to achieve the aforementioned objective, the present invention provides a wireless microprocessor module. The wireless microprocessor module includes a carrier board, having an upper surface and a lower surface; a wireless microprocessor circuit structure, provided on the upper surface of the carrier board; at least one antenna pin, provided on the lower surface of the carrier board and electrically connected to the wireless microprocessor circuit structure; and an antenna connection buckle, provided on the upper surface of the carrier board and electrically connected to the wireless microprocessor circuit structure and the at least one antenna pin.

In some embodiments, the wireless microprocessor circuit structure includes a wireless microprocessor core, a front-end chip and a memory, the front-end chip is electrically connected to the wireless microprocessor core, the front-end chip is electrically connected to the antenna connection buckle through the at least one antenna pin, and the memory is electrically connected to the wireless microprocessor core.

In some embodiments, the wireless microprocessor circuit structure further includes a quartz oscillator electrically connected to the wireless microprocessor core.

In some embodiments, an oscillation frequency of the quartz oscillator is 32 MHz.

In some embodiments, the wireless microprocessor core is wafer-level chip scale packaging (WLCSP).

In some embodiments, a size of the carrier board is 12 mm×16 mm.

In some embodiments, the wireless microprocessor circuit structure further includes a Near Field Communication (NFC) module electrically connected to the wireless microprocessor core.

In some embodiments, a size of the carrier board is 12 mm×16 mm or 16 mm×20 mm.

In some embodiments, the front-end chip is further electrically connected to a Universal Subscriber Identity Module (USIM) Card.

In some embodiments, the carrier board is a circuit board or a semiconductor carrier board.

In order to make the above objectives, features and advantages of the present invention more obvious and understandable, the specific embodiments listed in the drawings are described in detail below.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a block diagram of a wireless microprocessor module according to a first embodiment of the present invention.

FIG. 2 is a top view of the wireless microprocessor module according to the first embodiment of the present invention.

FIG. 3 is a bottom view of the wireless microprocessor module according to the first embodiment of the present invention.

FIG. 4 is a block diagram of a wireless microprocessor module according to a second embodiment of the present invention.

FIG. 5 is a top view of the wireless microprocessor module according to the second embodiment of the present invention.

FIG. 6 is a bottom view of the wireless microprocessor module with a different size according to the second embodiment of the present invention.

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

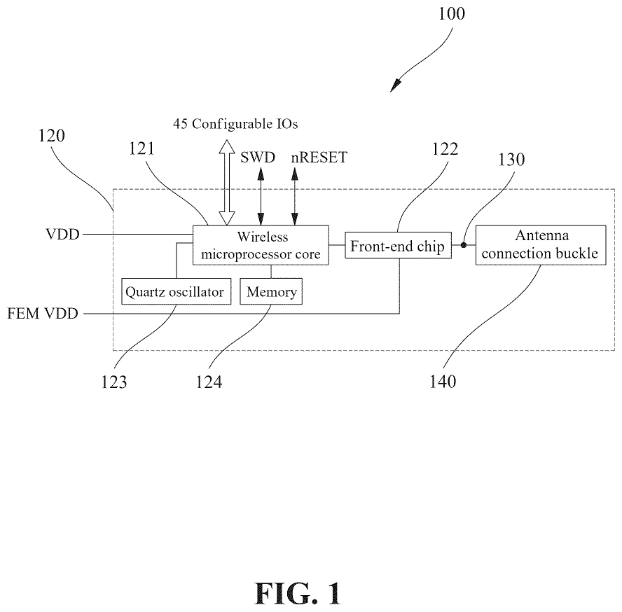

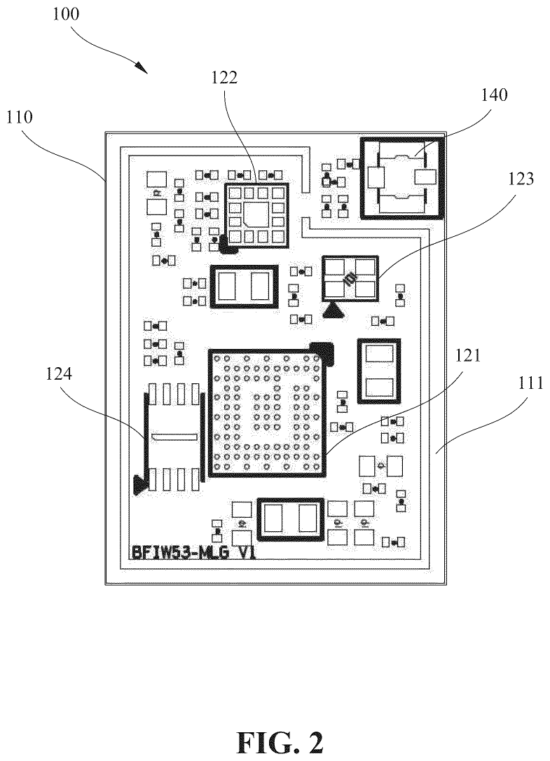

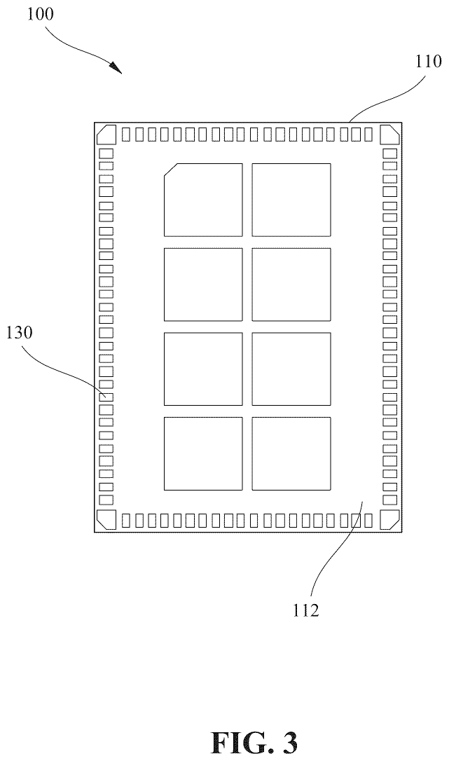

FIG. 1 is a block diagram of a wireless microprocessor module according to a first embodiment of the present invention. FIG. 2 is a top view of the wireless microprocessor module according to the first embodiment of the present invention. FIG. 3 is a bottom view of the wireless microprocessor module according to the first embodiment of the present invention. The wireless microprocessor module of the present invention may be defined as BFi53MLG.

With reference to FIGS. 1 to 3, the wireless microprocessor module 100 of the present invention includes a carrier board 110, a wireless microprocessor circuit structure 120, at least one antenna pin 130 and an antenna connection buckle 140.

The carrier board 110 may have an upper surface 111 (see FIG. 2) and a lower surface 112 (see FIG. 3). In some embodiments, the carrier board 110 may be a circuit board or a semiconductor carrier board, but not limited thereto. In this embodiment, a size of the carrier board 110 may be 12 mm×16 mm.

With reference to FIGS. 1 and 2, the wireless microprocessor circuit structure 120 may be disposed on the upper surface 111 of the carrier board 110. The wireless microprocessor circuit structure 120 may include a wireless microprocessor core 121, a front-end chip 122 and a memory 124. The front-end chip 122 may be electrically connected to the wireless microprocessor core 121, and the front-end chip 122 may be electrically connected to the antenna pin 130. The memory 124 may be electrically connected to the wireless microprocessor core 121. In this embodiment, the wireless microprocessor core 121 may be ARM Cortex-M33 with 2.4 GHz Lower Power RF, but not limited thereto. In some embodiments, the memory 124 may be QSPI (Quad Serial Peripheral Interface) 2M-byte flash memory, but not limited thereto. In some embodiments, the operating voltage (VDD) of the wireless microprocessor core 121 may be 2.7V˜5.5V. In some embodiments, the front-end chip 122 may be a front-end module (FEM) to enhance the signal emitted from the wireless microprocessor core 121, thereby preventing the emitted signal from being affected by noise interference. In some embodiments, the operating voltage (FEM VDD) of the front-end chip 122 may be 2.7V˜3.6V.

With reference to FIG. 1 and FIG. 3, the antenna pin 130 may be disposed on the lower surface 112 of the carrier board 110, the antenna pin 130 may be electrically connected to the antenna connection buckle 140, and the antenna pin 130 may be electrically connected to the front-end chip 122.

With reference to FIG. 1 and FIG. 3, the antenna connection buckle 140 may be disposed on the upper surface 111 of the carrier board 110, and the antenna connection buckle 140 may electrically connect the wireless microprocessor circuit structure 120 and the antenna pin 130. That is to say, the antenna connection buckle 140 may be electrically connected to the wireless microprocessor core 121 of the wireless microprocessor circuit structure 120. In some embodiments, the antenna connection buckle 140 may be a small radio frequency connector, such as i.PEX, but not limited thereto. In this way, the wireless microprocessor module 100 of the present invention may have an antenna connection buckle 140 built through the antenna pin 130, which can be directly connected to an antenna device (not shown).

With reference to FIG. 1, in some embodiments, the wireless microprocessor circuit structure 120 may further include a quartz oscillator 123 electrically connected to the wireless microprocessor core 121. In some embodiments, an oscillation frequency of the quartz oscillator 123 may be 32 MHz to provide a stable circuit frequency of the wireless microprocessor core 121.

With reference to FIG. 1, in some embodiments, the wireless microprocessor module 100 of the present invention further includes at least 45 configurable input/outputs (configurable IOs) (i.e., 45 pins), a program-downloading pin SWD and a reset pin nRESET. The 45 configurable input/output pins (configurable IOs) may be used for data or signal input and output; the program-downloading pin SWD may be used to download updated programs to the wireless microprocessor core 121 for updates; and the reset pin nRESET may be used to receive a signal to reset the wireless microprocessor core 121.

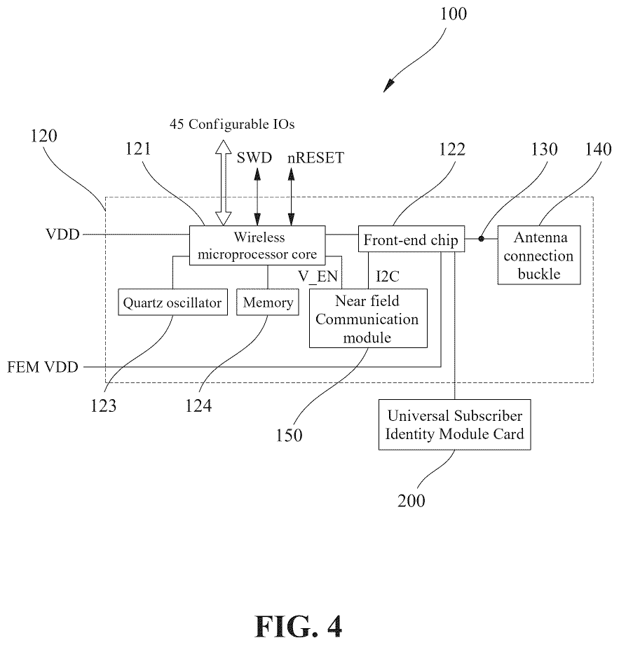

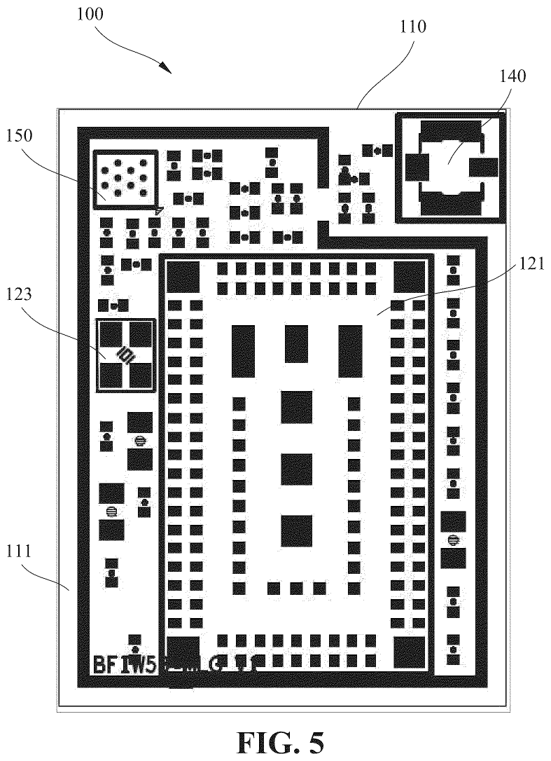

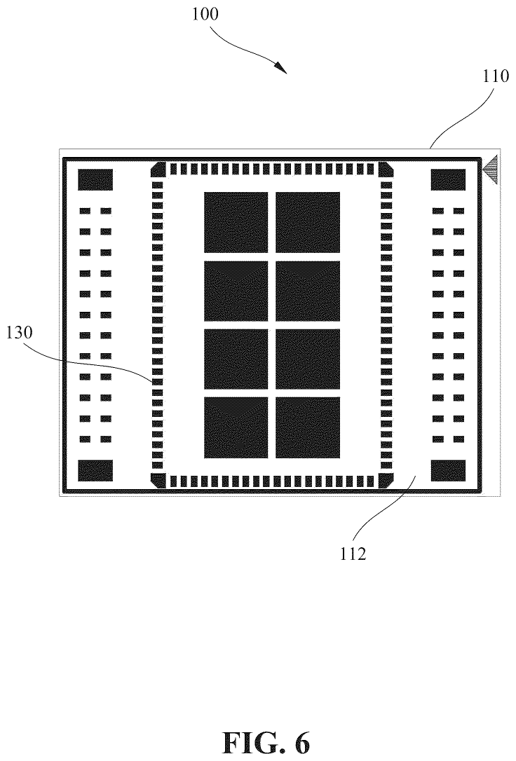

FIG. 4 is a block diagram of a wireless microprocessor module according to a second embodiment of the present invention. FIG. 5 is a top view of the wireless microprocessor module according to the second embodiment of the present invention. FIG. 6 is a bottom view of the wireless microprocessor module with a different size according to the second embodiment of the present invention. The wireless microprocessor module of the second embodiment is similar to the wireless microprocessor module of the first embodiment, and the difference therebetween is that the wireless microprocessor module of the second embodiment includes a Near Field Communication (NFC) module 150, and the wireless microprocessor core 121 of the second embodiment is ARM Cortex-M33 with NBIOT/LTE-M/DECT-NR+. Therefore, the operating voltage (VDD) of the wireless microprocessor core 121 of the second embodiment may be 3V˜5.5V. The same components of the wireless microprocessor module of the second embodiment as those of the wireless microprocessor module of the first embodiment use the same numerals. Their structures and functions are similar or identical and will not be described again.

With reference to FIGS. 4 and 5, in this embodiment, the near field communication (NFC) module 150 may be electrically connected to the wireless microprocessor core 121. The communication between the near field communication module 150 and the wireless microprocessor core 121 is performed through an activation signal path V_EN and a data path I2C. The activation signal path V_EN is used to provide parameters to the wireless microprocessor core 121 to perform corresponding parameter execution functions; the data path I2C is used to transmit data from the wireless microprocessor core 121 to the near field communication module 150, and then transmit to a near field communication reader (NFC Reader) (not shown). The near field communication reader may be, for example, a mobile phone for wireless communication, but not limited thereto.

In some embodiments, the front-end chip 122 may be further electrically connected to a Universal Subscriber Identity Module (USIM) Card 200 to identify the user's identity and enhance the security of the wireless microprocessor module 100 of the present invention.

In some embodiments, the size of the carrier board 110 of this embodiment may be 12 mm×16 mm (as shown in FIGS. 2, 3 and 5) or 16 mm×20 mm (as shown in FIG. 6). When the size is 12 mm×16 mm (see FIGS. 2, 3 and 5), the wireless microprocessor module 100 of this embodiment may be defined as BFi913MLG (1216), and its size is the same as the BFi53MLG defined by the wireless microprocessor module 100 of the first embodiment; when the size is 16 mm×20 mm (see FIG. 6), the wireless microprocessor module 100 of this embodiment may be defined as BFi915MLG (1620), thereby distinguishing it from the BFi53MLG defined by the wireless microprocessor module 100 of the first embodiment.

In summary, the wireless microprocessor module 100 of the present invention has an antenna connection buckle 140 built through the antenna pin 130, which can be directly connected to an antenna device (not shown); furthermore, the wireless microprocessor core 121 can enhance the emitted signal through the front-end chip 122 to avoid serious interference from noises.

The above descriptions are only used to explain the preferred embodiments of the present invention, and are not intended to limit the present invention in any form. Therefore, any modifications or changes made to the present invention under the same inventive spirit should still be included in the scope of protection intended by the present invention.

What is claimed is:

1. A wireless microprocessor module, comprising:
a carrier board, having an upper surface and a lower surface;
a wireless microprocessor circuit structure, provided on the upper surface of the carrier board;
at least one antenna pin, provided on the lower surface of the carrier board and electrically connected to the wireless microprocessor circuit structure; and
an antenna connection buckle, provided on the upper surface of the carrier board and electrically connected to the wireless microprocessor circuit structure and the at least one antenna pin.

2. The wireless microprocessor module according to claim 1, wherein the wireless microprocessor circuit structure includes a wireless microprocessor core, a front-end chip and a memory, the front-end chip is electrically connected to the wireless microprocessor core, the front-end chip is electrically connected to the antenna connection buckle through the at least one antenna pin, and the memory is electrically connected to the wireless microprocessor core.

3. The wireless microprocessor module according to claim 2, wherein the wireless microprocessor circuit structure further includes a quartz oscillator electrically connected to the wireless microprocessor core.

4. The wireless microprocessor module according to claim 3, wherein an oscillation frequency of the quartz oscillator is 32 MHz.

5. The wireless microprocessor module according to claim 2, wherein the wireless microprocessor core is wafer-level chip scale packaging (WLCSP).

6. The wireless microprocessor module according to claim 1, wherein a size of the carrier board is 12 mm×16 mm.

7. The wireless microprocessor module according to claim 2, wherein the wireless microprocessor circuit structure further comprises a Near Field Communication (NFC) module electrically connected to the wireless microprocessor core.

8. The wireless microprocessor module according to claim 7, wherein a size of the carrier board is 12 mm×16 mm or 16 mm×20 mm.

9. The wireless microprocessor module according to claim 7, wherein the front-end chip is further electrically connected to a Universal Subscriber Identity Module (USIM) Card.

10. The wireless microprocessor module according to claim 1, wherein the carrier board is a circuit board or a semiconductor carrier board.
